(19) United States
(12) Patent Application Publication
(10) Pub. No.: US 2025/0241170 A1
(43) Pub. Date: Jul. 24, 2025

(54) DISPLAY PANEL, DISPLAY DEVICE, AND PREPARATION METHOD FOR DISPLAY PANEL

(71) Applicants: Kunshan New Flat Panel Display Technology Center Co., Ltd., Kunshan (CN); Hefei Visionox Technology Co., Ltd., Hefei (CN)

(72) Inventors: Xiaokang ZHOU, Kunshan (CN); Xingxing CHEN, Kunshan (CN); Hajime YAMAGUCHI, Hefei (CN); Kunjing ZHONG, Kunshan (CN); Qingrong REN, Kunshan (CN); Rubo XING, Kunshan (CN)

(73) Assignees: Kunshan New Flat Panel Display Technology Center Co., Ltd., Kunshan (CN); Hefei Visionox Technology Co., Ltd., Hefei (CN)

(21) Appl. No.: 19/008,546

(22) Filed: Jan. 2, 2025

(30) Foreign Application Priority Data
Jan. 19, 2024 (CN) 202410084384.3

(51) Int. Cl. H10K 59/00; G06V 40/13; H10K 39/34; H10K 50/155; H10K 59/35; H10K 101/30

(52) U.S. Cl. CPC H10K 59/771; G06V 40/1318; H10K 39/34; H10K 50/155; H10K 59/35; H10K 2101/30

(57) ABSTRACT

The disclosure provides a display panel, a display device and a preparation method for the display panel. The display panel includes: a substrate having a first side; a light-emitting unit arranged on the first side, the light-emitting unit including a first hole transport layer; and a photoelectric sensor unit arranged on the first side, sensor unit and the photoelectric sensor unit includes a second hole transport layer, a photoelectric conversion layer and a buffer layer, the buffer layer being arranged on a side of the photoelectric conversion layer facing the second hole transport layer; where the first hole transport layer and the second hole transport layer are made of the same material, the buffer layer has a first electrical conductivity, and the second hole transport layer has a second electrical conductivity, the first electrical conductivity being greater than the second electrical conductivity.

### CROSS REFERENCE TO RELATED APPLICATION

The present application claims priority to Chinese Patent Application No. 202410084384.3 filed on Jan. 19, 2024, which is incorporated herein by reference in its entirety.

### TECHNICAL FIELD

The disclosure relates to the technical field of display devices, and particularly to a display panel, a display device, a preparation method for the display panel.

### BACKGROUND ART

Biometric recognition plays an important role in smart phones and tablet computers. There are two common methods in the prior art, that is, facial recognition and fingerprint recognition. The fingerprint recognition involves an ultrasonic fingerprint, a capacitive fingerprint, an optical fingerprint, etc. The optical fingerprint has the advantages of high resolution, high sensitivity and the capability of performing life health inspection.

### SUMMARY OF THE INVENTION

Embodiments of the disclosure provide a display panel, a display device and a preparation method for the display panel, with a view to enhancing the performance of a photo detector in a display panel.

An embodiment of a first aspect of the disclosure provides a display panel, including: a substrate having a first side; a light-emitting unit arranged on the first side, the light-emitting unit including a first hole transport layer; and a photoelectric sensor unit arranged on the first side, where the photoelectric sensor unit is configured to receive an optical signal and generate a corresponding electrical signal from the optical signal, and the photoelectric sensor unit includes a second hole transport layer, a photoelectric conversion layer and a buffer layer, the buffer layer being arranged on a side of the photoelectric conversion layer facing the second hole transport layer; where the first hole transport layer and the second hole transport layer are made of the same material, the buffer layer has a first electrical conductivity, and the second hole transport layer has a second electrical conductivity, the first electrical conductivity being greater than the second electrical conductivity.

An embodiment in a second aspect of the disclosure further provides a display device, including a display panel according to any one of the above-described embodiments in the first aspect.

An embodiment in a third aspect of the disclosure further provides a preparation method for a display panel. The preparation method includes:
preparing, on a first side of a substrate, a first hole transport layer of a light-emitting unit and a second hole transport layer of a photoelectric sensor unit, where the photoelectric sensor unit is configured to receive an optical signal and generate a corresponding electrical signal from the optical signal, and the first hole transport layer and the second hole transport layer are made of the same material; and
preparing a buffer layer on a side of the second hole transport layer away from the substrate, where the buffer layer has a first electrical conductivity, and the second hole transport layer has a second electrical conductivity, the first electrical conductivity being greater than the second electrical conductivity.

The display panel provided in this embodiment of the disclosure includes the substrate, the light-emitting unit and the photoelectric sensor unit, the light-emitting unit being configured to achieve luminous display of the display panel, and the photoelectric sensor unit being configured to achieve a photoelectric sensing function of the display panel. The first hole transport layer of the light-emitting unit and the second hole transport layer of the photoelectric sensor unit are made of the same material, so that the first hole transport layer and the second hole transport layer can be prepared and formed in the same process step, which can simplify a preparation process of the display panel. The buffer layer is arranged between the photoelectric conversion layer and the second hole transport layer of the photoelectric sensor unit, the electrical conductivity of the buffer layer is greater than the electrical conductivity of the second hole transport layer, and a potential barrier between the buffer layer and the photoelectric conversion layer is small, so that a potential barrier between the second hole transport layer and the photoelectric conversion layer can be reduced, the extraction efficiency of photogenerated holes can be improved, and thus the performance of an optical sensor unit can be enhanced. Therefore, according to this embodiment of the disclosure, the performance of a photo detector of the display panel can be enhanced by adding the buffer layer between the photoelectric conversion layer and the second hole transport layer.

### BRIEF DESCRIPTION OF THE DRAWINGS

By reading the following detailed description made with reference to the drawings for non-limiting embodiments, the other features, objectives and advantages of the disclosure will become more apparent, in which the same or similar features are denoted by the same or similar reference numerals.

FIG. 1 is a schematic structural diagram of a display panel according to a related embodiment;

FIG. 2 is a schematic diagram of a layer structure of a display panel according to a related embodiment;

FIG. 3 is a schematic diagram of an energy level structure of a display panel according to a related embodiment;

FIG. 4 is a schematic diagram of a layer structure of a display panel according to an embodiment of the disclosure;

FIG. 5 is a schematic diagram of an energy level structure of a display panel according to an embodiment of the disclosure;

FIG. 6 is a schematic diagram of a layer structure of a display panel according to another embodiment of the disclosure;

FIG. 7 is a schematic diagram of an energy level structure of a display panel according to another embodiment of the disclosure;

FIG. 8 is a schematic diagram of a layer structure of a display panel according to a further embodiment of the disclosure;

FIG. 9 is a schematic diagram of a layer structure of a display panel according to yet another embodiment of the disclosure;

FIG. 10 is a graph of a test of a display panel according to an embodiment of the disclosure; and

FIG. 11 is a schematic diagram of a preparation flow of a display panel according to an embodiment of the disclosure.

### LIST OF REFERENCE SIGNS

100. Substrate; 110. First electrode; 120. Second electrode;
210. Hole transport layer; 211. First sublayer; 212. Second sublayer; 220. Hole blocking layer; 230. Hole injection layer; 240. Electron transport layer;
310. Light-emitting structure; 320. Photoelectric sensing structure; 321. Hybrid layer; 322. Donor layer; 323. Acceptor layer;
400. Buffer Layer.

### DETAILED DESCRIPTION OF EMBODIMENTS

The features and exemplary embodiments of the disclosure in various aspects will be described in detail below. In the following detailed description, many specific details are set forth to comprehensively understand the disclosure. However, it will be very apparent to those skilled in the art that the disclosure may be implemented without some of these specific details. The following description of the embodiments are merely to provide a better understanding for the disclosure by illustrating examples of the disclosure. In the drawings and the following description, at least part of known structures and techniques are not shown to avoid unnecessary ambiguousness of the disclosure; and for the ease of clarity, the dimensions of part of the structure may be enlarged. In addition, the features, structures or characteristics described below may be combined, in any suitable manner, in one or more embodiments.

In the description of the disclosure, it should be noted that “a plurality of” means two or more, unless otherwise specified. The orientation or position relationship indicated by the terms “upper”, “lower”, “left”, “right”, “inner”, “outer”, etc. is merely for the convenience of describing the disclosure and simplifying the description, rather than indicating or implying that a device or element referred to must have a particular orientation or be constructed and operated in a particular orientation, and therefore should not be construed as limiting the disclosure. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the disclosure. In the description of the disclosure, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection. For those of ordinary skill in the art, the specific meanings of the terms mentioned above in the disclosure may be construed according to specific circumstances.

Biometric recognition plays an important role in mobile terminals such as smart phones and tablet computers. There are two common methods in the prior art, that is, facial recognition and fingerprint recognition. The fingerprint recognition involves an ultrasonic fingerprint, a capacitive fingerprint, an optical fingerprint, etc. The optical fingerprint has become the mainstream technical means thanks to its advantages of high resolution, high sensitivity and the capability of performing life health inspection.

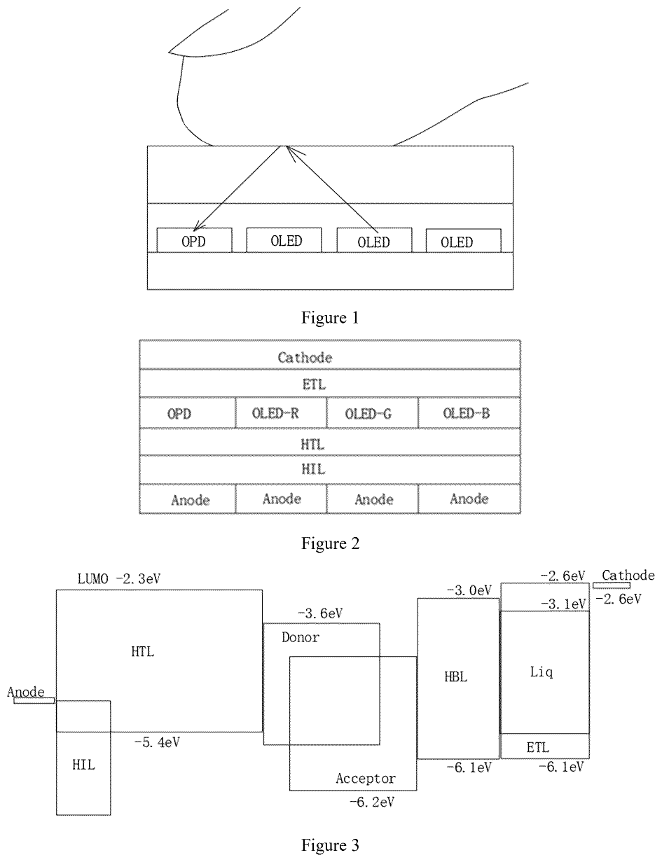

FIG. 1 shows a display panel provided in the related art, and a light transmission path is shown by arrows in FIG. 1. It should be noted that a larger integrated area and a thinner overall thickness can be achieved by jointly integrating organic light emitting diodes and photoelectric sensors in the panel. An organic photo detector (OPD) prepared on the basis of an organic photosensitive material is compatible with a vacuum evaporation process for an organic light emitting diode (OLED), which is an important direction for integrating fingerprint recognition into a panel in the future.

As shown in FIG. 2, the OPD typically includes a cathode, anodes, an active layer (or referred to as a photosensitive layer) and a carrier layer, and is a photoelectric device that converts an incident light signal into an electrical signal, while the organic light emitting diode is a device that converts an electrical signal into an optical signal.

The active layer of the OPD generally includes two organic materials with energy levels staggered, where one of the materials is a donor, and a typical donor includes a copper phthalocyanine oligomer (chemical symbol: CuPc), butyl phthalate (abbreviated as: DBP), etc.; and the other material is an acceptor, and a typical acceptor includes fullerenes (for example, C60 and C70, where C60 is a molecule composed of 60 carbon atoms, C60 is also referred to as buckyball, and C70 is a molecule composed of 70 carbon atoms). An operating principle of the OPD may include the following steps which respectively involve: the materials absorbing light to generate excitons; the excitons diffusing to a donor-acceptor interface; the excitons diffusing to the donor-acceptor interface and being subject to charge separation; and charge transport and collection. In order to improve the efficiency of exciton dissociation, the donor and the acceptor are typically mixed together (co-evaporated) to serve as the active layer.

In order to increase the efficiency of carrier collection, a reverse bias voltage, such as −3V, is generally additionally applied to the cathode and the anodes of the OPD. However, this reverse voltage also increases the injection of dark currents.

The OPD is generally configured to implement a photoelectric sensing function. For example, the OPD may be used for image recognition. Further, when the OPD is configured to implement fingerprint recognition, the OPD is required to have a higher recognition precision, and therefore the OPD needs to have a higher signal to interference plus noise ratio (SNR). It should be noted that the magnitude of the signal to interference plus noise ratio is related to external quantum efficiency (EQE) in the OPD. Specifically, the EQE represents a ratio of the number of photoelectrons running through the device to the number of photons entering the device during illumination, that is, the capability of converting light into electricity. The EQE is the most basic parameter of the OPD, and therefore maximizing the EQE is the direction of OPD device optimization and product performance improvement.

In an integrated application of OPD and OLED, in consideration of the costs and process difficulties, the OPD needs to share some carrier layers with the OLED, as shown in FIG. 3. Although this integration method is cost-effective, the performance of the OPD device is also reduced. Moreover, each of the OPD and the OLED is configured to include a thick hole transport layer (HTL) that is capable of effectively blocking the injection of anode electrons during reverse bias and lowering a dark current. However, since the hole transport layer is very thick, causing a large resistance. Further, the energy level of a highest occupied molecular orbital (HOMO) of the hole transport layer does not match the HOMO energy level of a donor in a photoelectric sensing structure (that is, there is a potential barrier). Therefore, the extraction of photogenerated holes is hampered, and thus the OPD device provided with the thick hole transport layer has a very low EQE.

In order to solve the above-described technical problem, during an OPD and OLED integrated application of an embodiment of the disclosure, an interfacial modification film layer is introduced in an OPD device structure so as to solve the above-described problem that the extraction of the photogenerated holes is hampered, and to improve the EQE of the OPD device.

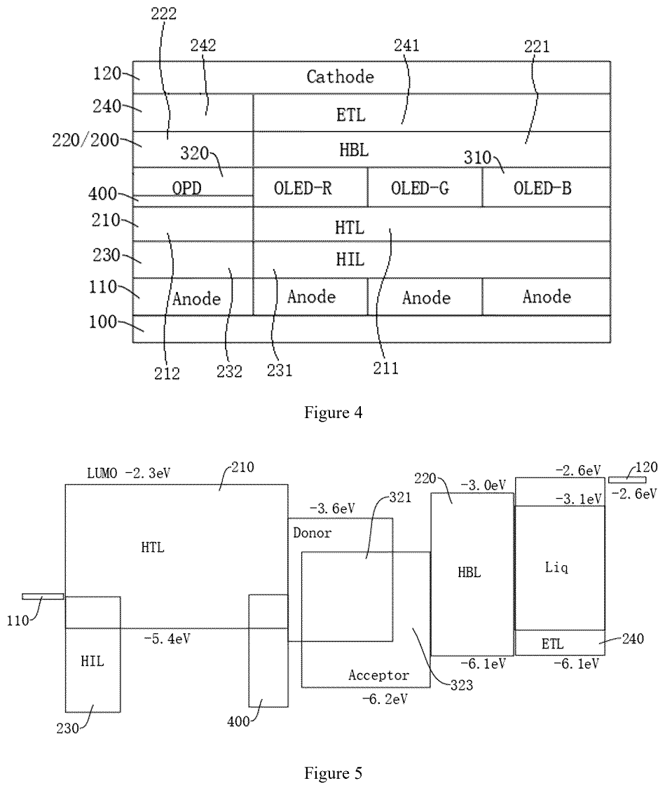

In order to better understand the disclosure, a display panel and a display device according to the embodiments of the disclosure will be described in detail below with reference to FIGS. 4 to 10.

Referring to FIGS. 4 and 5 together, FIG. 4 is a schematic diagram of a layer structure of a display panel according to an embodiment of the disclosure; and FIG. 5 is a schematic diagram of an energy level structure of a display panel according to an embodiment of the disclosure.

As shown in FIGS. 4 and 5, the display panel according to the embodiment in a first aspect of the disclosure includes: a substrate 100 having a first side; a light-emitting unit arranged on the first side, the light-emitting unit including a first hole transport layer 211; and a photoelectric sensor unit arranged on the first side, the photoelectric sensor unit being configured to receive an optical signal and generate a corresponding electrical signal from the optical signal, and the photoelectric sensor unit including a second hole transport layer 212, a photoelectric conversion layer 320 and a buffer layer 400, the buffer layer 400 being arranged on a side of the photoelectric conversion layer 320 facing the second hole transport layer 212; where the first hole transport layer 211 and the second hole transport layer 212 are made of the same material, the buffer layer 400 has a first electrical conductivity, and the second hole transport layer 212 has a second electrical conductivity, the first electrical conductivity being greater than the second electrical conductivity.

Optionally, the light-emitting unit includes a light-emitting layer 310, the light-emitting layer 310 being located on a side of the first hole transport layer 211 away from the substrate 100.

The display panel provided in the embodiment of the disclosure includes the substrate 100, the light-emitting unit and the photoelectric sensor unit, the light-emitting unit being configured to achieve luminous display of the display panel, and the photoelectric sensor unit being configured to achieve a photoelectric sensing function of the display panel. The first hole transport layer 211 of the light-emitting unit and the second hole transport layer 212 of the photoelectric sensor unit are made of the same material, so that the first hole transport layer 211 and the second hole transport layer 212 can be prepared and formed in the same process step, which can simplify a preparation process of the display panel. The buffer layer 400 is arranged between the photoelectric conversion layer 320 and the second hole transport layer 212 of the photoelectric sensor unit, the electrical conductivity of the buffer layer 400 is greater than the electrical conductivity of the second hole transport layer 212, and a potential barrier between the buffer layer 400 and the photoelectric conversion layer 320 is small, so that a potential barrier between the second hole transport layer 212 and the photoelectric conversion layer 320 can be reduced, the extraction efficiency of the photogenerated holes can be improved, and thus the performance of an optical sensor unit can be enhanced. Therefore, according to the embodiment of the disclosure, the performance of a photo detector of the display panel can be enhanced by adding the buffer layer 400 between the photoelectric conversion layer 320 and the second hole transport layer 212.

Optionally, the first hole transport layer 211 and the second hole transport layer 212 are integrally provided as a hole transport layer 210. That is, the first hole transport layer 211 and the second hole transport layer 212 are two parts at different positions on the same film layer, the first hole transport layer 211 is a part of the hole transport layer 210 that is stacked with the light-emitting layer 310, and the second hole transport layer 212 is a part of the hole transport layer 210 that is stacked with the photoelectric conversion layer 320. Optionally, in other implementations, there may also be a spacing between the first hole transport layer 211 and the second hole transport layer 212.

Optionally, the light-emitting unit is a structure for converting an electrical signal into an optical signal to achieve the luminous display of the display panel. Optionally, the photoelectric sensor unit is a structure for converting an optical signal line into an electrical signal so as to achieve the photoelectric detection function of the display panel. Optionally, the photoelectric sensor unit is the OPD device mentioned above.

Optionally, the display panel further includes a first electrode 110 and a second electrode 120, the first electrode 110 and the second electrode 120 being respectively arranged on two sides of the light-emitting unit and the photoelectric sensor unit; and the first electrode 110 and the second electrode 120 can drive the light-emitting unit to emit light, and the first electrode 110 and the second electrode 120 can also transmit a signal of the photoelectric sensor unit. Optionally, the substrate 100 further includes a drive circuit for driving the light-emitting unit to emit light.

Optionally, one of the first electrode 110 and the second electrode 120 is an anode, and the other is a cathode. An embodiment of the disclosure is exemplified by using the first electrode 110 as the anode and the second electrode 120 as the cathode. A material of the first electrode 110 may include indium tin oxide, and a material of the second electrode 120 may include magnesium (chemical symbol: Mg), silver (chemical symbol: Ag), ytterbium (chemical symbol: Yb), etc.

There are a variety of methods to set the position of the buffer layer 400, for example, the buffer layer 400 may be directly located between the second hole transport layer 212 and the photoelectric conversion layer 320, that is, the buffer layer 400 is attached to the photoelectric conversion layer 320, and the shortest distance d between the buffer layer 400 and the photoelectric conversion layer 320 is zero. In this implementation, since the electrical conductivity of the buffer layer 400 is greater than the electrical conductivity of the second hole transport layer 212, causing the electrical conductivity of the buffer layer 400 to be greater than the electrical conductivity of the hole transport layer 210, the problem is solved that the extraction of the photogenerated holes is hampered due to the excessively thick hole transport layer 210 having the large resistance.

In addition, since the electrical conductivity of the buffer layer 400 is greater than the electrical conductivity of the second hole transport layer 212, the potential barrier between the buffer layer 400 and the photoelectric conversion layer 320 is smaller, and it is possible to better mitigate the problem of the extraction of the photogenerated holes being hampered by a potential barrier between the hole transport layer 210 and the photoelectric conversion layer 320.

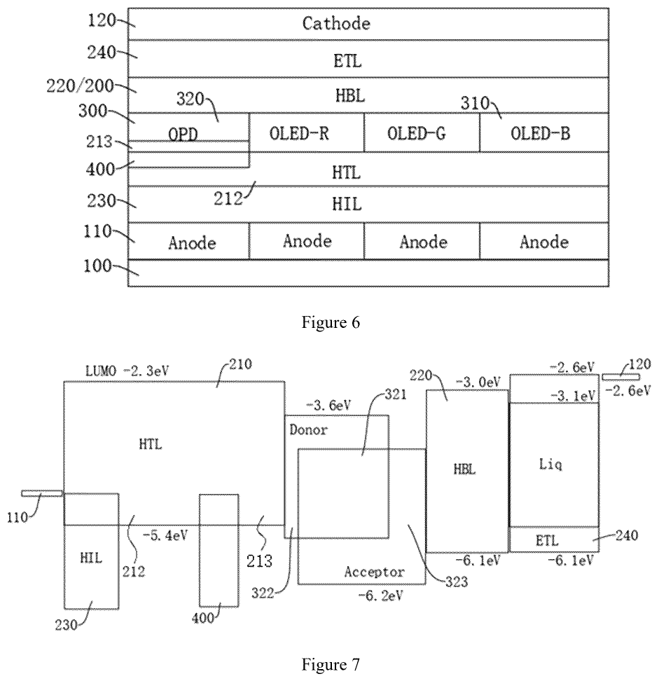

Alternatively, in other embodiments, as shown in FIGS. 6 and 7, the hole transport layer 210 includes a third hole transport layer 213, that is, the photoelectric sensor unit further includes the third hole transport layer 213, the third hole transport layer 213 being arranged on a side of the buffer layer 400 away from the second hole transport layer 212, and the photoelectric conversion layer 320 being arranged on a side of the third hole transport layer 213 away from the buffer layer 400.

In these embodiments, the second hole transport layer 212 and the third hole transport layer 213 are respectively arranged on two sides of the buffer layer 400. That is, since the third hole transport layer 213 is arranged between the photoelectric conversion layer 320 and the buffer layer 400, the shortest distance d between the buffer layer 400 and the photoelectric conversion layer 320 is not zero. By adding the buffer layer 400 between the second hole transport layer 212 and the third hole transport layer 213, the overall electrical conductivity of the second hole transport layer 212 and the third hole transport layer 213 can be improved. It is possible not only to solve the problem that the extraction of the photogenerated holes is hampered due to the excessively thick hole transport layer 210 having the large resistance, but also to reduce the potential barrier between the hole transport layer 210 and the photoelectric conversion layer 320, thereby mitigating the problem of the extraction of the photogenerated holes being hampered by a potential barrier between the hole transport layer 210 and the photoelectric conversion layer 320.

In any one of the above-described embodiments, when the photoelectric sensor unit includes the third hole transport layer 213, the third hole transport layer 213 has a first thickness that is not greater than 50 nanometers. It should be noted that the first thickness is not greater than 50 nanometers, that is, the shortest distance d between the buffer layer 400 and the photoelectric conversion layer 320 is less than or equal to 50 nanometers; and in such a thickness setting manner, it is possible to ensure that the third hole transport layer 213 has an appropriate thickness, and then ensure that there is an appropriate distance between the buffer layer 400 and the photoelectric conversion layer 320, thereby effectively mitigating the problem of the potential barrier existing between the hole transport layer 210 and the photoelectric conversion layer 320.

Optionally, when the photoelectric sensor unit includes the third hole transport layer 213, the third hole transport layer 213 has the first thickness that is not greater than 50 nanometers and not less than 3 nanometers. It should be noted that when the first thickness is within the above range, it is possible to mitigate the problem of the blocking effect thereof on electrons being excessively small due to the excessive small first thickness, and also to mitigate the problem of the extraction of the photogenerated holes being hampered and the EQE being reduced due to the excessively large first thickness.

In some optional embodiments, the display panel further includes a hole injection layer 230, the hole injection layer 230 being arranged on a side of the hole transport layer 210 facing the substrate 100. The hole injection layer 230 includes a first hole injection layer 231 and a second hole injection layer 232. For example, the light-emitting unit includes a first hole injection layer 231, and the photoelectric sensor unit includes a second hole injection layer 232, the first hole injection layer 231 being arranged on a side of the first hole transport layer 211 facing the substrate 100, and the second hole injection layer 232 being arranged on a side of the second hole transport layer 212 facing the substrate 100.

Optionally, the buffer layer 400 and the hole injection layer 230 are spaced apart, for example, the buffer layer 400 and the second hole injection layer 232 are spaced apart.

In these embodiments, the second hole injection layer 232 and the buffer layer 400 are spaced apart, and the hole transport layer 210 (e.g., the second hole transport layer 212) may be arranged between the second hole injection layer 232 and the buffer layer 400, so as to improve the hole transport efficiency.

Optionally, the first hole injection layer 231 and the second hole injection layer 232 may be made of the same material, that is, the first hole injection layer 231 and the second hole injection layer 232 may be prepared and formed in the same process step, which can simplify the preparation process of the display panel.

Optionally, the first hole injection layer 231 and the second hole injection layer 232 are of an integrated structure, for example, the first hole injection layer 231 and the second hole injection layer 232 are different regions on the same hole injection layer 230. Optionally, in other implementations, there may also be a spacing between the first hole injection layer 231 and the second hole injection layer 232.

Optionally, the display panel may further include a hole blocking layer 220 and an electron transport layer 240.

Optionally, the light-emitting unit further includes a first electron transport layer 241, the first electron transport layer 241 being arranged on a side of the first hole transport layer 211 away from the substrate 100; and the photoelectric sensor unit further includes a second electron transport layer 242, the second electron transport layer 242 being arranged on a side of the photoelectric conversion layer 320 away from the second hole transport layer 212. Optionally, the electron transport layer 240 includes the first electron transport layer 241 and the second electron transport layer 242, that is, the first electron transport layer 241 and the second electron transport layer 242 may be arranged integrally, and there may also be a spacing between the first electron transport layer 241 and the second electron transport layer 242.

Optionally, the hole blocking layer 220 includes a first hole blocking layer 221 and a second hole blocking layer 222, the first hole blocking layer 221 and the first hole transport layer 211 being arranged in a stacked manner, and the second hole blocking layer 222 and the second hole transport layer 212 being arranged in a stacked manner. Optionally, the light-emitting unit further includes the first hole blocking layer 221, the first hole blocking layer 221 being arranged on a side of the first electron transport layer 241 facing the substrate 100; and the photoelectric sensor unit further includes the second hole blocking layer 222, the second hole blocking layer 222 being located on a side of the second electron transport layer 242 facing the substrate 100. Optionally, the first hole blocking layer 221 and the second hole blocking layer 222 may be of an integrated structure, and there may also be a spacing between the first hole blocking layer 221 and the second hole blocking layer 222.

The buffer layer 400 is arranged in a variety of materials, and the material of the buffer layer 400 may be the same as the material of the second hole injection layer 252.

In some optional embodiments, the material of the buffer layer 400 includes a first buffer material, the first buffer material being an organic P-type dopant and/or an inorganic P-type dopant; and/or the first buffer material is a metal material. By configuring the buffer layer 400 to include the organic P-type dopant, the inorganic P-type dopant or the metal material, the electrical conductivity of the buffer layer 400 can be improved, so that the electrical conductivity of the buffer layer 400 is greater than the electrical conductivity of the second hole transport layer 212, it is then possible to solve the problem that the extraction of the photogenerated holes is hampered due to the excessively thick hole transport layer 210 having the large resistance, and also to mitigate the problem that there is a potential barrier between the second hole transport layer 212 and the photoelectric conversion layer 320.

Optionally, when the first buffer material is the organic P-type dopant, the buffer layer 400 has a lowest unoccupied molecular orbital (LUMO) energy level of not greater than −4.0 electron volts.

When the first buffer material is the organic P-type dopant, the first buffer material may include at least one of NDP-9, 2,3,6,7,10,11-hexacyano-1,4,5,8,9,12-hexaazatriphenylene (abbreviated as: HAT-CN), and 2,3,5,6-tetrafluoro-7,7′,8,8′-tetracyanoquinodimethane (abbreviated as: F4-TCNQ).

When the first buffer material is the inorganic P-type dopant, the inorganic P-type dopant includes at least one of molybdenum trioxide (chemical symbol: MoO₃), vanadium pentoxide (chemical symbol: V₂O₅) and tungsten trioxide (chemical symbol: WO₃).

Optionally, when the first buffer material is the inorganic P-type dopant, the energy level of electrical conductivity of the buffer layer 400 is not greater than −4.5 electron volts.

Optionally, the material of the buffer layer 400 may be formed by blending other materials and the first buffer material. Alternatively, the material of the buffer layer 400 is the first buffer material, that is, the buffer layer 400 does not include other materials. When the material of the buffer layer 400 is the first buffer material, for example, when the material of the buffer layer 400 is the organic P-type dopant or the inorganic P-type dopant, the buffer layer 400 has a second thickness that is not less than 0.1 nanometers and not greater than 20 nanometers. Therefore, it is possible to well mitigate the problem of the extraction of the photogenerated holes being hampered due to the insufficient electrical conductivity of the excessively thin buffer layer 400, and also to solve the problem of lateral crosstalk due to lateral electric leakage of the excessively thick buffer layer 400.

In other optional embodiments, the first buffer material may be a metal material and has a work function of greater than 4.0 electron volts. The first buffer material is a high-work-function material, the electrical conductivity of the first buffer material can be improved, and thus the electrical conductivity of the entire buffer layer 400 can be improved, so as to solve the problem that the extraction of the photogenerated holes is hampered due to the excessively thick hole transport layer 210 having the large resistance, and also to better mitigate the problem of the extraction of the photogenerated holes being hampered by a potential barrier between the hole transport layer 210 and the photoelectric conversion layer 320.

When the first buffer material is the metal material, the first buffer material may include at least one of silver (chemical symbol: Ag), gold (chemical symbol: Au), aluminum (chemical symbol: Al), copper (chemical symbol: Cu), and chromium (chemical symbol: Cr), such that the first buffer material has a good electrical conductivity.

As described above, the buffer layer 400 may be the first buffer material, that is, the material of the buffer layer 400 is a single-layer organic P-type dopant and/or a single-layer inorganic P-type dopant and/or a single-layer metal material. For example, the buffer layer 400 is a metal silver layer, etc.

In other optional embodiments, the material of the buffer layer 400 further includes a first bulk material, and the buffer layer 400 is obtained by doping the first buffer material in the first bulk material.

In these optional embodiments, the material of the buffer layer 400 includes the first host material doped with the first buffer material, the first host material and the first buffer material being blended to adjust the electrical conductivity of the buffer layer 400 to be in an appropriate range.

Optionally, the hole transport layer 210 includes a second bulk material, and the first host material may be the same as the second host material to simplify the preparation process of the display panel.

Optionally, the first host material may include at least one of 4,4′-cyclohexylidenebis[N,N-bis(4-methylphenyl)benzenamine] (abbreviated as: TAPC), tris(4-carbazoyl-9-ylphenyl)amine (abbreviated as: TCTA), N,N′-bis-(1-naphthalenyl)-N,N′-bis-phenyl-(1,1′-biphenyl)-4,4′-diamine (abbreviated as: NPB), and 4,4′,4″-Tris[2-naphthylphenylamino]triphenylamine (abbreviated as: 2-TNATA), and the electrical conductivity of the buffer layer 400 can be adjusted to be in an appropriate range by selecting an appropriate first host material and an appropriate blending ratio.

Optionally, when the material of the buffer layer 400 includes the first host material and the first buffer material, the buffer layer 400 has a third thickness that is not less than 0.1 nanometers and not greater than 50 nanometers, so as to well mitigate the problem of the extraction of the photogenerated holes being hampered due to the insufficient electrical conductivity of the excessively thin buffer layer 400, and also to solve the problem of lateral crosstalk due to lateral electric leakage of the excessively thick buffer layer 400.

Optionally, the first buffer material has an amount of a first substance, the material of the buffer layer has an amount of a second substance, and the ratio of the amount of the first substance to the amount of the second substance is not less than 0.01% and not greater than 50%. Thus, the first buffer material and the first host material are blended more uniformly, have a larger contact area, and can better improve the electrical conductivity of the buffer layer 400.

In some optional embodiments, the buffer layer 400 has a first hole carrier concentration, and the second hole transport layer 212 has a second hole carrier concentration, the first hole carrier concentration being greater than the second hole carrier concentration. During use of the display panel, the hole carrier concentration in the buffer layer 400 is greater than the hole carrier concentration in the second hole transport layer 212, such that the potential barrier between the buffer layer 400 and the photoelectric conversion layer 320 is smaller.

The buffer layer 400 may be a single-layer structural body, that is, the buffer layer 400 is prepared and formed by the same material in the same process step.

Alternatively, the buffer layer 400 includes two or more sublayers that may be prepared and formed in different process steps. The two or more sublayers may be made of the same or different materials, and by adjusting the materials of different sublayers, a potential barrier between the buffer layer 400 and the hole transport layer 210 can be reduced, and the potential barrier between the buffer layer 400 and the photoelectric conversion layer 320 can be reduced.

Optionally, an orthographic projection of the photoelectric conversion layer 320 on the substrate 100 is located within an orthographic projection of the buffer layer 400 on the substrate 100, so that the buffer layer 400 can be correspondingly arranged at different positions of the photoelectric conversion layer 320 to better mitigate the problem of a large potential barrier between the photoelectric conversion layer 320 and the hole transport layer 210.

Optionally, the photoelectric conversion layer 320 and the buffer layer 400 may be arranged in a one-to-one correspondence manner, that is, the orthographic projection of each photoelectric conversion layer 320 on the substrate 100 is located within the orthographic projection of the corresponding buffer layer 400 on the substrate 100 to mitigate the problem of a large potential barrier between each photoelectric conversion layer 320 and the hole transport layer 210.

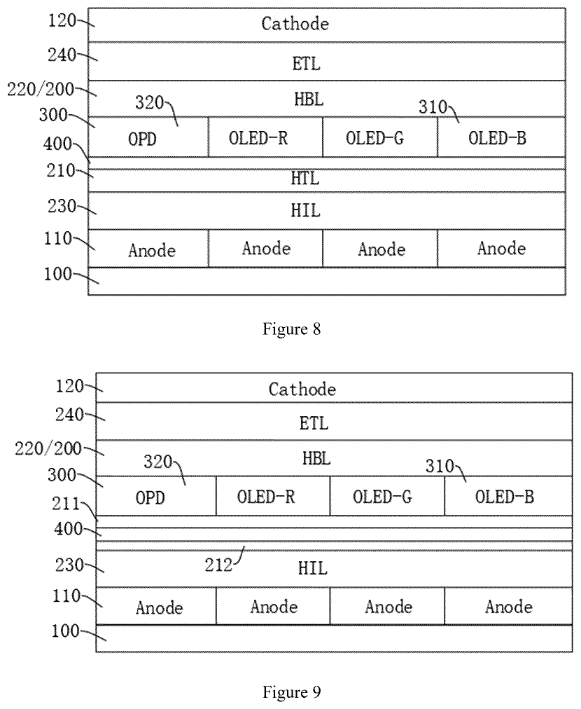

Alternatively, as shown in FIGS. 8 and 9, in some implementations, the buffer layer 400 may be a common layer. Specifically, orthographic projections of the first hole transport layer 211 and the second hole transport layer 212 on the substrate 100 overlap with the orthographic projection of the buffer layer 400 on the substrate 100. For example, the first hole transport layer 211 and the second hole transport layer 212 are integrated as the hole transport layer 210, and the buffer layer 400 may be prepared and formed by using the same mask as the hole transport layer 210 so as to simplify the preparation process of the display panel.

In some optional embodiments, the photoelectric conversion layer 320 includes a donor and an acceptor, the donor and the acceptor interacting with each other to achieve the photoelectric sensing function.

Optionally, the photoelectric conversion layer 320 includes a hybrid layer 321, a material of the hybrid layer 321 including a donor and an acceptor to reduce a potential barrier between the photoelectric conversion layer 320 and other layer structures.

Optionally, the photoelectric conversion layer 320 further includes a donor layer 322, the donor layer 322 being located on a side of the hybrid layer 321 facing the substrate 100, and a material of the donor layer 322 including the donor; and/or the photoelectric conversion layer 320 further includes an acceptor layer 323, the acceptor layer 323 being located on a side of the hybrid layer 321 away from the substrate 100, and a material of the acceptor layer 323 including the acceptor.

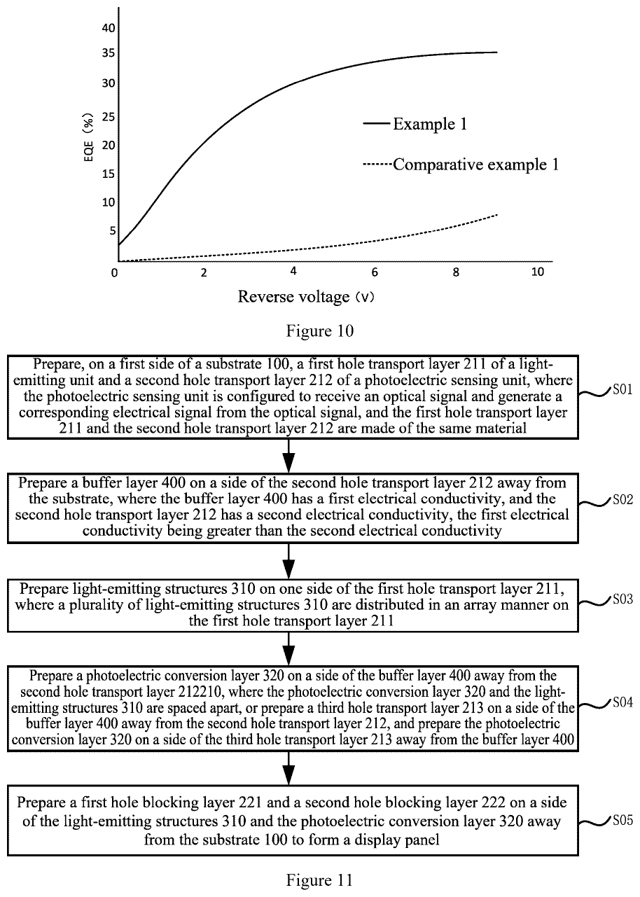

In order to further illustrate the beneficial effects of the disclosure, referring to FIG. 10, the inventors have performed experiments of comparative examples. Comparative examples include: comparative example 1 and example 1, both of which provide a display panel including a light-emitting unit and a photoelectric sensor unit.

The differences between example 1 and comparative example 1 lie in that the buffer layer 400 is introduced between the photoelectric conversion layer 320 and the second hole transport layer 212 in the photoelectric sensor unit, and the third hole transport layer 213 between the buffer layer 400 and the photoelectric sensor unit has a thickness of 20 nanometers, the buffer layer 400 has a thickness of 5 nanometers, and the buffer layer 400 is made of the same material as the hole injection layer 230.

By testing comparative example 1 and example 1 mentioned above in the case of incident light having a wavelength of 590 nanometers, a graph as shown in FIG. 10 is obtained. The horizontal coordinate in FIG. 10 represents a reverse voltage applied to the OPD. It can be obviously seen from FIG. 10 that the EQE in comparative example 1 is very low when no buffer layer 400 is provided. However, the EQE of the display panel is significantly improved by 25% after the buffer layer 400 is introduced. It is indicated that, the arrangement of the buffer layer 400 can not only solve the problem that the extraction of the photogenerated holes is hampered due to the excessively thick hole transport layer 210 having the large resistance, but also significantly reduce an interfacial potential barrier between the hole transport layer 210 and the photoelectric conversion layer 320.

An embodiment in a second aspect of the disclosure further provides a display device, including a display panel according to any one of the above-described embodiments in the first aspect. Since the display device according to the embodiment in the second aspect of the disclosure includes the display panel according to any one of the above-described embodiments in the first aspect, the display device according to the embodiment in the second aspect of the disclosure has the beneficial effects of the display panel according to any one of the above-described embodiments in the first aspect, which will not be repeated herein.

The display device in the embodiment of the disclosure includes, but is not limited to devices having a display function, such as a cell phone, a personal digital assistant (PDA), a tablet computer, an e-book, a television, an access control, a smart fixed-line telephone, or a control console.

An embodiment in a third aspect of the disclosure further provides a preparation method for a display panel. The display panel may be a display panel according to any one of the above-described embodiments in the first aspect. Referring to FIGS. 1 to 11 together, the preparation method for the display panel may include:
step S01, preparing, on a first side of a substrate 100, a first hole transport layer 211 of a light-emitting unit and a second hole transport layer 212 of a photoelectric sensor unit, where the photoelectric sensor unit is configured to receive an optical signal and generate a corresponding electrical signal from the optical signal, and the first hole transport layer 211 and the second hole transport layer 212 are made of the same material.
step S02, preparing a buffer layer 400 on a side of the second hole transport layer 212 away from the substrate, where the buffer layer 400 has a first electrical conductivity, and the second hole transport layer 212 has a second electrical conductivity, the first electrical conductivity being greater than the second electrical conductivity.

Optionally, the method may further include:
step S03, preparing light-emitting layers 310 on one side of the first hole transport layer 211, where a plurality of light-emitting layers 310 are distributed in an array manner on the first hole transport layer 211;
step S04, preparing a photoelectric conversion layer 320 on a side of the buffer layer 400 away from the second hole transport layer 212210, where the photoelectric conversion layer 320 and the light-emitting layers 310 are spaced apart, or preparing a third hole transport layer 213 on a side of the buffer layer 400 away from the second hole transport layer 212, and preparing the photoelectric conversion layer 320 on a side of the third hole transport layer 213 away from the buffer layer 400; and
step S05, preparing a first hole blocking layer 221 and a second hole blocking layer 222 on a side of the light-emitting layers 310 and the photoelectric conversion layer 320 away from the substrate 100 to form a display panel.

Optionally, the sequence of step S02 and step S03 may be that step S02 is performed before or after step S03. Optionally, when step S03 is performed after step S02, the preparation and forming in the same process step may be achieved in step S03 and step S04 to simplify the preparation process of the display panel.

The display panel prepared by the method provided in the embodiment of the disclosure includes the substrate 100, the light-emitting unit and the photoelectric sensor unit, the light-emitting unit being configured to achieve the luminous display of the display panel, and the photoelectric sensor unit being configured to achieve the photoelectric sensing function of the display panel. The first hole transport layer 211 of the light-emitting unit and the second hole transport layer 212 of the photoelectric sensor unit are made of the same material, so that the first hole transport layer 211 and the second hole transport layer 212 can be prepared and formed in the same process step, which can simplify the preparation process of the display panel. The buffer layer 400 is arranged between the photoelectric conversion layer 320 and the second hole transport layer 212 of the photoelectric sensor unit, the electrical conductivity of the buffer layer 400 is greater than the electrical conductivity of the second hole transport layer 212, and the potential barrier between the buffer layer 400 and the photoelectric conversion layer 320 is small, which can not only solve the problem that the extraction of the photogenerated holes is hampered due to the excessively thick hole transport layer 210 having the large resistance, but also significantly reduce the potential barrier between the second hole transport layer 212 and the photoelectric conversion layer 320, thereby further improving the extraction efficiency of the photogenerated holes, and thus enhancing the performance of the photoelectric sensor unit. Therefore, according to the embodiment of the disclosure, the performance of photoelectric sensing of the display panel can be enhanced by adding the buffer layer 400 between the photoelectric conversion layer 320 and the second hole transport layer 212.

Optionally, the buffer layer 400 and the photoelectric conversion layer are arranged adjacent to each other, and the orthographic projection of the photoelectric conversion layer 320 on the substrate 100 overlaps with the orthographic projection of the buffer layer 400 on the substrate 100, so that the buffer layer 400 and the photoelectric conversion layer 320 can be prepared by using the same precision mask in steps S02 and S04 to simplify the preparation process of the display panel.

Although the disclosure is described with reference to the preferred embodiments, various modifications can be made, and equivalents can be provided to substitute for the components thereof without departing from the scope of the disclosure. In particular, the technical features mentioned in the embodiments can be combined in any manner, provided that there is no structural conflict. The disclosure is not limited to the specific embodiments disclosed herein but includes all the technical solutions that fall within the scope of the claims.

What is claimed is:

1. A display panel, comprising:
a substrate having a first side;
a light-emitting unit arranged on the first side, the light-emitting unit comprising a first hole transport layer; and
a photoelectric sensor unit arranged on the first side, wherein the photoelectric sensor unit is configured to receive an optical signal and generate a corresponding electrical signal according to the optical signal, and the photoelectric sensor unit comprises a second hole transport layer, a photoelectric conversion layer and a buffer layer, the buffer layer being arranged on a side of the photoelectric conversion layer facing the second hole transport layer;
wherein the first hole transport layer and the second hole transport layer are made of the same material, the buffer layer has a first electrical conductivity, and the second hole transport layer has a second electrical conductivity, the first electrical conductivity being greater than the second electrical conductivity.

2. The display panel according to claim 1, wherein
the buffer layer and the photoelectric conversion layer are arranged adjacent to each other; or the photoelectric sensor unit further comprises a third hole transport layer, the third hole transport layer being arranged on a side of the buffer layer away from the second hole transport layer, and the photoelectric conversion layer being arranged on a side of the third hole transport layer away from the buffer layer;
the photoelectric sensor unit comprises a third hole transport layer, the third hole transport layer having a first thickness that is not greater than 50 nanometers;
the first thickness is not greater than 50 nanometers and not less than 3 nanometers.

3. The display panel according to claim 1, wherein
the first hole transport layer and the second hole transport layer are of an integrated structure.

4. The display panel according to claim 1, wherein a material of the buffer layer comprises a first buffer material, wherein:
the first buffer material comprises at least one of an organic P-type dopant, an inorganic P-type dopant or a metallic material.

5. The display panel according to claim 4, wherein the first buffer material is the organic P-type dopant, and a LUMO energy level of the buffer layer is not greater than −4.0 electron volts;
the organic P-type dopant comprises at least one of NDP-9, 2,3,6,7,10,11-hexacyano-1,4,5,8,9,12-hexaazatriphenylene, and 2,3,5,6-tetrafluoro-7,7′,8,8′-tetracyanoquinodimethane;
the first buffer material is the inorganic P-type dopant, and the energy level of electrical conductivity of the buffer layer is not greater than −4.5 electron volts;
the inorganic P-type dopant comprises at least one of molybdenum trioxide, vanadium pentoxide and tungsten trioxide;
the first buffer material is the metal material, and a work function of the buffer layer is greater than 4.0 electron volts; and
the first buffer material is the metal material that comprises at least one of silver, gold, aluminum, copper and chromium.

6. The display panel according to claim 4, wherein the material of the buffer layer is the first buffer material, and the buffer layer has a second thickness that is not less than 0.1 nanometers and not greater than 20 nanometers.

7. The display panel according to claim 4, wherein the buffer layer further comprises a first host material doped with the first buffer material, and the second hole transport layer comprises a second bulk material, the first host material being the same as the second bulk material;
the first host material comprises at least one of 4,4′-cyclohexylidenebis[N,N-bis(4-methylphenyl)benzenamine], tris(4-carbazoyl-9-ylphenyl)amine, N,N′-bis-(1-naphthalenyl)-N,N′-bis-phenyl-(1,1′-biphenyl)-4,4′-diamine, and 4,4′,4″-Tris[2-naphthylphenylamino]triphenylamine;
the buffer layer has a third thickness that is not less than 0.1 nanometers and not greater than 50 nanometers; and
the first buffer material has an amount of a first substance, the material of the buffer layer has an amount of a second substance, and the ratio of the amount of the first substance to the amount of the second substance is not less than 0.01% and not greater than 50%.

8. The display panel according to claim 1, wherein the buffer layer has a first hole carrier concentration, and the second hole transport layer has a second hole carrier concentration, the first hole carrier concentration being greater than the second hole carrier concentration.

9. The display panel according to claim 1, wherein the buffer layer is a single-layer structure, or the buffer layer comprises two or more sublayers; and
the two or more sublayers are made of the same or different materials.

10. The display panel according to claim 1, wherein an orthographic projection of the photoelectric conversion layer on the substrate is located within an orthographic projection of the buffer layer on the substrate; and
orthographic projections of the first hole transport layer and the second hole transport layer on the substrate overlap with the orthographic projection of the buffer layer on the substrate.

11. The display panel according to claim 1, wherein the photoelectric conversion layer comprises a donor material and an acceptor material;
the photoelectric conversion layer comprises a hybrid layer that comprises the donor and the acceptor;
the photoelectric conversion layer further comprises a donor layer, the donor layer being located on a side of the hybrid layer facing the substrate and comprising the donor; or the photoelectric conversion layer further comprises an acceptor layer, the acceptor layer being located on a side of the hybrid layer away from the substrate and comprising the acceptor.

12. The display panel according to claim 1, wherein the light-emitting unit further comprises a first hole injection layer, the first hole injection layer being arranged on a side of the first hole transport layer facing the substrate, and the photoelectric sensor unit further comprises a second hole injection layer, the second hole injection layer being arranged on a side of the second hole transport layer facing the substrate;
the first hole injection layer and the second hole injection layer are made of the same material;
the first hole injection layer and the second hole injection layer are of an integrated structure;
the light-emitting unit further comprises a first electron transport layer, the first electron transport layer being arranged on a side of the first hole transport layer away from the substrate, and the photoelectric sensor unit further comprises a second electron transport layer, the second electron transport layer being arranged on a side of the photoelectric conversion layer away from the second hole transport layer; and
the light-emitting unit further comprises a first hole blocking layer, the first hole blocking layer being arranged on a side of the first electron transport layer facing the substrate, and the photoelectric sensor unit further comprises a second hole blocking layer, the second hole blocking layer being located on a side of the second electron transport layer facing the photoelectric conversion layer.

13. The display panel according to claim 1, wherein the light-emitting unit further comprises a light-emitting structure, the light-emitting structure is located on the side of the first hole transport layer away from the substrate, and at least part of the photoelectric conversion layer and the light-emitting structure are located on the same layer.

14. A display device, comprising a display panel according to claim 1.

15. A preparation method for a display panel, comprising:
preparing, on a first side of a substrate, a first hole transport layer of a light-emitting unit and a second hole transport layer of a photoelectric sensor unit, wherein the photoelectric sensor unit is configured to receive an optical signal and generate a corresponding electrical signal from the optical signal, and the first hole transport layer and the second hole transport layer are made of the same material; and
preparing a buffer layer on a side of the second hole transport layer away from the substrate, wherein the buffer layer has a first electrical conductivity, and the second hole transport layer has a second electrical conductivity, the first electrical conductivity being greater than the second electrical conductivity.

16. The preparation method according to claim 15, wherein the method further comprises posterior to the step of preparing a buffer layer on a side of the second hole transport layer away from the substrate:
preparing a photoelectric conversion layer on a side of the buffer layer away from the second hole transport layer; or
preparing a third hole transport layer on a side of the buffer layer away from the second hole transport layer, and preparing a photoelectric conversion layer on a side of the third hole transport layer away from the buffer layer;
the first hole transport layer and the second hole transport layer are formed in the same process step; and
the buffer layer and the photoelectric conversion layer are prepared by using the same precision mask.
